(19) United States
(12) Patent Application Publication
(10) Pub. No.: US 2012/0225568 A1
(43) Pub. Date: Sep. 6, 2012

(54) ANNEALING METHOD AND ANNEALING APPARATUS

(75) Inventors: Yusaku IZAWA, Nirasaki-Shi (JP); Junjun LIU, Austin, TX (US); Hongyu YUE, Austin, TX (US); Dorel TOMA, Austin, TX (US)

(73) Assignee: Tokyo Electron Limited, Tokyo (JP)

(21) Appl. No.: 13/406,763

(22) Filed: Feb. 28, 2012

Related U.S. Application Data
(60) Provisional application No. 61/448,848, filed on Mar. 3, 2011.

(51) Int. Cl. H01L 21/26; B23K 26/42; B23K 26/12; B23K 26/08

(52) U.S. Cl. 438/795; 219/121.65; 219/121.77; 219/121.8; 219/121.82; 219/121.86; 257/E21.328

(57) ABSTRACT

An annealing method irradiates a target object, having a film formed on its surface, with a laser beam to perform an annealing process to the target object. The surface of the target object is irradiated with the laser beam obliquely at an incident angle that is determined to achieve an improved laser absorptance of the film.

### CROSS REFERENCE TO RELATED APPLICATION

The present application is based on and claims the benefit of priority from U.S. provisional application No. 61/448,848 filed on Mar. 3, 2011, the entire contents of which are incorporated herein by reference.

### TECHNICAL FIELD

The present invention relates to a method and apparatus for annealing a film formed on a surface of a target object, such as a semiconductor wafer.

### BACKGROUND ART

In general, in order to manufacture a semiconductor device or the like, various processes, such as a film deposition process, an etching process, an oxidation process, an annealing process and a modification process, are repeatedly performed to a semiconductor wafer such as a silicon substrate. Among these processes, the annealing process heats a semiconductor wafer to a predetermined temperature, in order to improve properties of a film formed on a surface of the semiconductor wafer. Recently, in order to expedite the annealing process and in order not to overheat a portion built in a semiconductor wafer, the surface of the semiconductor wafer is scanned by a laser beam to rapidly anneal the surface part (see, for example, WO2010/001727).

When annealing a silicon oxide film, or a silica-series film containing Si—O bonds, such as a so-called Low-k film having a low dielectric constant, which is formed on a surface of a semiconductor wafer W, the annealing process is performed by using a carbon dioxide laser, with a far infrared laser beam having a wavelength of about 9.4 μm, which is an absorptance peak of the Si—O bonds.

In a conventional annealing apparatus, an annealing process is performed by: accommodating a semiconductor wafer W to be annealed in a processing vessel; irradiating a laser beam substantially vertically onto the wafer W from above (an incident angle is substantially 0 degrees) through a transmission window provided on a ceiling part of the processing vessel; and scanning the laser beam all over the surface of the wafer W.

When the laser beam is irradiated in the above manner, there is a possibility that the laser beam might not be efficiently absorbed by a film formed on the surface of the semiconductor wafer, since the film thickness is small with respect to the wavelength of the far infrared laser beam. If the laser beam transmits through the film and the wafer to a certain degree, the reflected light on the front surface of the film, and a reflected laser beam reflected on the film and a reflected laser beam reflected on the back surface of the wafer interfere with each other. Thus, due to slight variation in irradiation angle (incident angle) of the laser beam and allowable variation in wafer thickness, the laser absorptance is greatly increased or decreased, whereby reproducibility of the annealing process is impaired.

### SUMMARY OF THE INVENTION

The present invention provides an annealing method and an annealing apparatus capable of significantly improving the laser absorption efficiency.

According to the present invention, there is provided an annealing method that irradiates a target object, having a film formed on its surface, with a laser beam to perform an annealing process to the target object, wherein the surface of the target object is irradiated with the laser beam obliquely at an incident angle that is determined to achieve an improved laser absorptance of the film.

In addition, according to the present invention, there is provided an annealing apparatus that irradiates a target object, having a film formed on its surface, with a laser beam to perform an annealing process to the target object, the annealing apparatus including: a processing vessel configured to accommodate the target object; a laser beam irradiation window provided on the processing vessel; a stage disposed in the processing vessel to hold the target object; a laser beam irradiation unit configured to deliver a laser beam onto the surface of the target object through the laser beam irradiation window such that the surface of the target object is irradiated with the laser beam obliquely at an incident angle that is determined to achieve an improved laser absorptance of the film; a gas supply unit configured to supply a process gas into the processing vessel; and an exhaust unit configured to discharge an atmosphere in the processing vessel.

According to the present invention, since the laser beam is incident obliquely on the surface of the target object, the laser absorption efficiency can be significantly improved. In addition, an influence of the variation in thickness of the target objects can be reduced, whereby a stable annealing process can be performed.

### BRIEF DESCRIPTION OF DRAWINGS

FIG. 1 is a configuration diagram showing a first embodiment of an annealing apparatus according to the present invention.

FIG. 2 is a graph showing a relationship between an incident angle and a p-polarized light absorptance, when a metal film is provided below a film.

FIG. 3 is a graph showing a relationship between an incident angle and a p-polarized light absorptance, when a metal film is not provided below the film.

FIG. 4 is a schematic configuration diagram showing a second embodiment of the annealing apparatus according to the present invention.

FIG. 5 is a configuration diagram showing a modified example in which a stage is rotatable.

### DETAILED DESCRIPTION OF EMBODIMENTS

Embodiments of an annealing method and an annealing apparatus according to the present invention will be described in detail below with reference to the drawings.

### First Embodiment

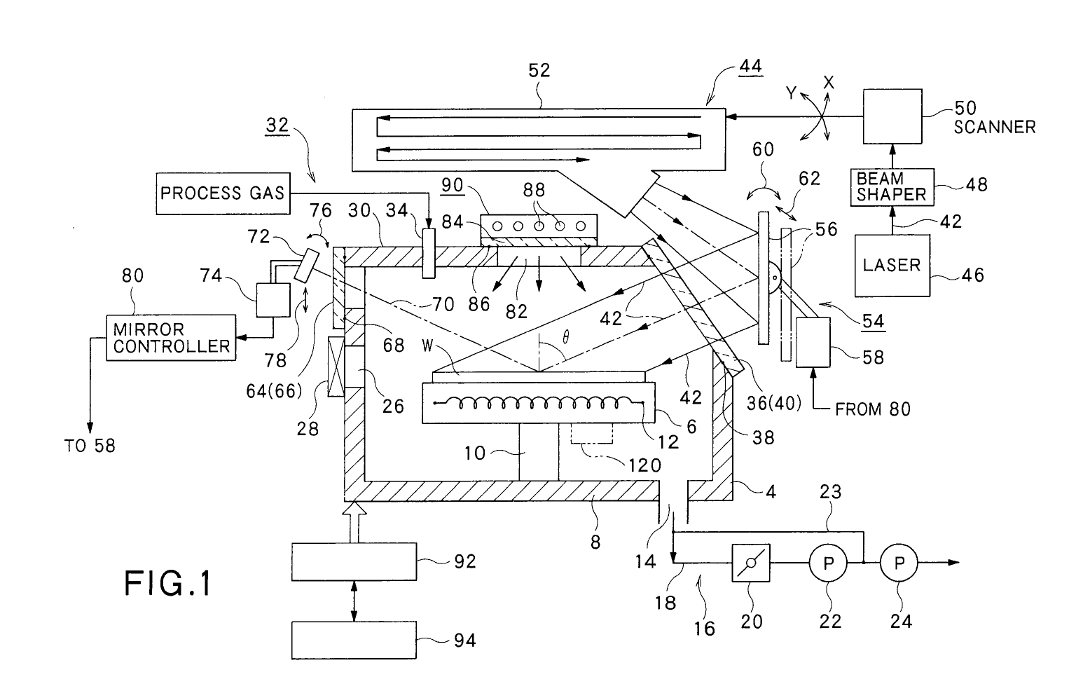

FIG. 1 is a configuration diagram showing a first embodiment of an annealing apparatus according to the present invention. As shown in FIG. 1, the annealing apparatus 2 includes a processing vessel 4 capable of accommodating therein a target object, such as a semiconductor wafer W. The processing vessel 4 has a box-like shape made of, e.g., aluminum, an aluminum alloy or a stainless steel.

Inside the processing vessel 4, a stage 6 configured to hold the wafer W is disposed. The stage 6 is supported by a column 10 standing from a bottom part 8 of the processing vessel 4. The wafer W can be placed on an upper surface of the stage 6. For example, a wafer having a diameter of 300 mm is used as the wafer W. The stage 6 is made of, e.g., aluminum, an aluminum alloy or a ceramic. A heater 12 for heating the wafer W is disposed inside the stage 6, so that the wafer W can be heated according to need. There is a case in which the heater 12 is not provided. The stage 6 is provided with a lifter pin (not shown) which is moved upward or downward, when the wafer W is loaded or unloaded.

An exhaust port 14 is formed in the bottom part 8 of the processing vessel 4. Connected to the exhaust port 14 is an exhaust system (exhaust unit) 16 configured to discharge an atmosphere in the processing vessel 4. The exhaust system 16 has an exhaust channel 18 connected to the exhaust port 14. A pressure regulating valve 20, a first pump 22 and a second pump 24 are disposed in that order, in the exhaust channel 18 from the upstream side thereof toward the downstream side thereof. The exhaust channel 18 is provided with a bypass line 23 that connects a point on the upstream side of the pressure regulating valve 20 and a point between the first and second pumps 22 and 24 to each other. The bypass line 23 has a not-shown open/close valve, whereby the inside of the processing vessel can be roughly decompressed in an early stage of evacuation.

A turbo molecular pump is used as the first pump 22, for example, and a dry pump is used as the second pump 24, for example, so that the inside of the processing vessel 4 can be in a highly vacuum state. A loading and unloading port 26 is formed in a sidewall of the processing vessel 4. The loading and unloading port 26 is provided with a gate valve 28 for airtightly closing and opening and the loading and unloading port 26.

A gas supplying section (gas supplying unit) 32 configured to supply a process gas is disposed on a ceiling part 30 of the processing vessel 4. The gas supplying section 32 has a gas nozzle 34 passing through the ceiling part 30. A process gas can be supplied from the gas nozzle 34 at a controlled flow rate according to need. Although O₂ gas and N₂ gas can be used as a process gas, the kind of process gas can be suitably changed depending on a type of annealing to be performed.

A laser beam irradiation window 36 through which a laser beam enters the inside of the processing vessel 4 is disposed obliquely above the stage 6. The laser-beam irradiation window 36 is formed by forming an opening in portions of the sidewall of the processing vessel 4 and the ceiling part 30 oriented to an oblique direction relative to the vertical direction, and airtightly fitting a ZnSe plate 40 via a sealing member 38 such as an O-ring. Thus, the laser-beam irradiation window 36 is positioned obliquely above the stage 6. Outside the processing vessel 4, there is disposed a laser-beam irradiation unit 44 configured to irradiate the surface of the wafer W with a laser beam 42 at an incident angle θ within a range of 30 degrees and 80 degrees. In this embodiment, although ZnSe is used as a laser beam-transmissive optical material, a suitable optical material can be selected depending on a type of the laser beam 42 to be used.

The laser beam irradiation unit 44 includes: a laser beam generator 46 configured to generate the laser beam 42; a beam shaper 48 configured to adjust the beam diameter and the beam profile of the laser beam 42; a scanner 50 configured to scan the laser beam 42 in two directions (e.g., X direction and Y direction) that are orthogonal to each other; and a multipath unit 52 configured to elongate a light path length of the laser beam 42; and an incident angle adjusting mirror unit 54 configured to adjust an incident angle of the laser beam 42 relative to the wafer W; which are disposed in that order along the light path of the laser beam 42.

As long as the light path has a sufficient length without the use of the multipath unit 52, the multipath unit 52 may be omitted. In addition, as long as the conversion of the laser beam 42 emitted from a laser oscillator 46 is high, the beam shaper 48 may be omitted.

A carbon gas dioxide laser oscillator may be used as the laser oscillator 46, for example. In this case, the laser oscillator 46 generates the far infrared laser beam 42 having a wavelength within a range between 8 μm and 10 μm, e.g., a wavelength of 9.4 μm. The laser oscillator 46 is configured to output only a laser beam that is p-polarized with respect to the wafer. By operating the scanner 50 so as to longitudinally and laterally scan the laser beam 42, the whole surface of the wafer W can be irradiated with the laser beam 42.

In the multipath unit 52, the laser beam 42 is repeatedly reflected, so that the light path length can be lengthend. As a result, when the scanner 50 swings the laser beam 42 through only small angles, a distance corresponding to the length of the diameter of the wafer W can be scanned by the laser beam 42. Thus, the whole surface of the wafer W can be irradiated with the laser beam 42 at substantially the same incident angle. Since the multipath unit 52 is a relatively large-sized structure, the multipath unit 52 is located above the processing vessel 4, in order to make smaller the footprint of the apparatus.

As described above, the incident angle adjusting mirror unit 54 is configured to adjust the incident angle θ of the laser beam which is finally incident on the surface of the wafer W. The incident angle θ is an angle defined by a direction perpendicular to the wafer surface (normal line direction) and a laser incident direction. The incident angle adjusting mirror unit 54 includes a reflection mirror 56 configured to reflect the laser beam 42 outputted from the multipath unit 52 toward the wafer W, and a mirror actuator 58 configured to move the reflection mirror 56. By operating the mirror actuator 58, the reflection mirror 56 can be turned, as shown by an arrow 60, to vary an orientation angle of the reflection mirror 56, as well as the reflection mirror 56 can be moved, as shown by an arrow 62, along an optical axis direction of the laser beam 42 incident on the reflection mirror 56.

By adjusting moving amounts in both the directions of the arrows 60 and 62, the incident angle of the laser beam 42 relative to the surface of the wafer W can be widely varied. To be specific, by operating the mirror actuator 58, the incident angle can be varied within a range between 30 degrees and 85 degrees at maximum. When the incident angle is not required to be widely varied, the moving mechanism of the mirror actuator 58, which moves the reflection mirror 56 in the direction of the arrow 62 along the optical axis direction, may be omitted.

A reflected light transmission window 64 is disposed on a sidewall of the processing vessel 4, which is opposite to the laser beam irradiation window 36 with respect to the stage 6. The reflected light transmission window 64 is formed by airtightly fitting a ZnSe plate 66 in an opening formed in the sidewall of the processing vessel 4, via a sealing member 68 such as an O-ring. Outside the reflected light transmission window 64, there is disposed a reflected light detector 72 configured to detect reflected light 70 of the laser beam, which is reflected on the surface of the wafer W. The reflected light detector 72 is formed of, e.g., an optical sensor. The reflected light detector 72 is attached to an actuator 74, whereby the reflected light detector 72 can be rotated, as shown by an arrow 76, to vary an inclination angle thereof, as well as the reflected light detector 72 can be moved upward and downward, as shown by an arrow 78, in order to properly receive the reflected light 70.

A detected value of the reflected light detector 72 is inputted to a mirror controller 80. Based on the detected value, the mirror controller 80 can adjust the reflection mirror 56 of the incident angle adjusting mirror unit 54 so as to be located at an optimum position at an optimum inclination angle.

A wide opening 82 is formed in the ceiling part of the processing vessel 4. A transmission plate 84 made of, e.g., quartz glass is airtightly fitted in the opening 82 via a sealing member 86 such as an O-ring. Outside the transmission plate 84, there is disposed an ultraviolet irradiation unit 90 having a plurality of ultraviolet lamps 88. Thus, the wafer can be irradiated with ultraviolet light according to need, so as to perform a modification process or the like. When an ultraviolet irradiation process is not needed, the ultraviolet irradiation unit 90 may be omitted.

The overall operation of the annealing apparatus 2 as structured above is controlled by an apparatus control unit 92 comprising a computer. A computer program for the operation is stored in a storage medium 94. The storage medium 94 comprises, e.g., a flexible disc, a CD (Compact Disc), a hard disc drive, a flash memory or a DVD. Specifically, by a command from the apparatus control unit 92, start and stop of the laser beam irradiation, start and stop of the gas supply, control of the gas flow rate, control of the process temperature and the process pressure, and so on are performed.

The apparatus control unit 92 has a user interface (not shown) to be connected thereto. The user interface is composed of a keyboard by which an operator can input and output a command for managing the apparatus, and a display which can visualize an operation condition of the apparatus. Further, communications for the foregoing controls to and from the apparatus control unit 92 may be performed through a communication line.

<Description of Annealing Method>

Next, an annealing method performed by using the annealing apparatus 2 as structured above is described. At first, the gate valve 28 provided on the sidewall of the processing vessel 4 is opened, and a semiconductor wafer W, which is a target object, is loaded into the processing vessel 4 by a transfer arm, not shown, through the loading and unloading port 26. Then, the wafer W is placed on the stage 6 through upward and downward movements of the lifter pin, not shown. Since the exhaust system 16 is driven beforehand, the inside of the processing vessel 4 is maintained in a vacuum state. A film to be annealed, e.g., a silica series film containing Si—O bonds, is formed on the surface of the wafer W. The silica series film may be a silicon oxide film (SiO₂) or an organo-silicate glass film having a low dielectric constant (OSG low-k film), for example.

After the wafer W has been placed on the stage 6, the gate valve 28 is closed so as to hermetically seal the inside of the processing vessel 4. Then, O₂ and N₂, as a process gas, are supplied from the gas supplying unit 32 at respective controlled flow rates, so that an atmosphere in the processing vessel 4 is maintained at a predetermined process pressure. Then, the incident angle of the laser beam is determined such that the laser absorptance can be maximized. This is because the laser absorptance differs depending on the thickness and the kind of the film formed on the wafer W.

To this end, the laser beam irradiation unit 44 is driven to emit the laser beam 42 of p-polarized light from the laser oscillator 46. The laser beam 42 is sequentially propagated through the beam shaper 48, the scanner 50 and the multipath unit 52. Further, the laser beam 42 is reflected on the reflection mirror 56 of the incident angle adjusting mirror unit 54, so that a predetermined position of the surface of the wafer W, e.g., a central portion thereof is irradiated with the laser beam 42. Thereafter, the reflected light 70 reflected on the surface of the wafer W is detected by the reflected light detector 72. At this time, the scanner 50 is not driven so that scanning of the laser beam 42 is not performed.

After that, the mirror actuator 58 of the incident angle adjusting mirror unit 54 is driven to move the reflection mirror 56 as shown by the arrow 62 and to rotate the reflection mirror 56 little by little as shown by the arrow 60. Thus, the incident angle θ of the laser beam 42 incident on the surface of the wafer W is varied little by little. At this time, in synchronization with the movement of the reflection mirror 56, the reflected light detector 72 is turned in the direction of the arrow 76 and moved in the direction of the arrow 78, so as to unfailingly detect the reflected light 70. The detected value of the reflected light detector 72 is inputted to the mirror controller 80.

Based on the detected value of the reflected light detector 72, the mirror controller 80 calculates the incident angle θ at which the intensity of light of the reflected light 70 is minimum, i.e., the incident angle θ at which the absorptance of the laser beam 42 is maximum. Then, in order that the calculated incident angle θ can be obtained, the mirror actuator 58 is controlled to adjust the position of the reflection mirror 56 in the anteroposterior direction and the rotation angle thereof, and the reflection mirror 56 is fixed at that position and at that rotation angle.

In this manner, the incident angle θ of the laser beam 42 is set such that a desired, improved laser absorptance of the film can be obtained, and the wafer surface is irradiated with the laser beam from obliquely above. In practical operation of scanning the laser beam, since the laser beam is scanned through predetermined swinging angles, the incident angle varies through very small angles in the plus and minus directions with respect to the above incident angle θ.

If the kind and the thickness of the film are known, an approximate value of the incident angle to the film at which the laser absorptance is the maximum is known. Thus, the amounts of moving and rotating the reflection mirror 56 may be very small, in order to determine the optimum incident angle θ. When the optimum incident angle θ is determined, it is preferable that the laser beam 42 is incident on the central portion of the wafer W as shown by the broken line in FIG. 1.

After the position of the reflection mirror 56 in the anteroposterior direction and the inclination angle thereof, which allow the laser beam 42 to be incident on the wafer W at the optimum incident angle θ, have been respectively set, the annealing process is performed succeedingly. In the annealing process, longitudinal and lateral (X direction and Y direction) scanning of the laser beam 42 is performed by driving the scanner 50 of the laser beam irradiation unit 44 with the reflection mirror 56 being fixed in order to irradiate the whole surface of the wafer W with the laser beam 42, so that rapid heating of the wafer is performed in a short time. As described above, since the laser beam 42 does not contain s-polarized light lowering the absorptance, but contains only p-polarized light, the laser absorptance can be remarkably improved.

As described above, since the laser beam 42 is swung only through slight angles with respect to the incident angle θ at which the absorptance of the film is maximum to scan the wafer in the diametrical direction, the laser absorptance can be improved all over the surface of the wafer W. In addition, since the laser beam 42 is applied to the surface of the wafer W from obliquely above, even when the laminate structure of the film(s) or the thickness of the wafer slightly vary, the annealing process can be stably performed, without large variation in laser absorptance which might be caused by interference between reflected lights, whereby reproducibility of the annealing process can be improved. For example, the allowable thickness range of 300-mm wafers is 775±25 μm. According to the present invention, reproducibility of the annealing process can be improved, without being adversely affected by the variation of the wafer thickness within the allowable range (±25 μm).

In addition, since the multipath unit 52 is provided to extend the light path length, the wafer W can be scanned over the diameter thereof only by slightly swinging the laser beam by the scanner 50. For example, the Brewster angle of a silica series film having a thickness of about 600 nm is about 70 degrees. In this case, if the optical light length from the scanner 50 to the wafer W is 500 mm, the swinging angle of the laser beam 42 ensuring that the whole diameter of a 300-mm wafer is scanned by the laser beam 42 is about 3 degrees, and the energy density varies about 15% at maximum.

On the other hand, if the light path length is lengthened to 6000 mm with the use of the multipath unit 52, the swinging angle of the laser beam 42 ensuring that the whole diameter of the wafer is scanned by the laser beam 42 is only about 0.3 degrees, and variation in energy density can be reduced to about 1.5%. Since the swinging angle of the laser beam 42 for scanning can be decreased, it is possible to suppress rotation of the polarized component due to the change of the irradiation angle, whereby irradiation of only p-polarized light can be achieved. Thus, the annealing process can be performed while maintaining improved laser absorptance all over the surface of the wafer W.

After the annealing process has been completed in the aforementioned manner, the ultraviolet irradiation unit 90 is driven so that the wafer W is irradiated with ultraviolet light emitted from the ultraviolet lamps 88, whereby the modification process is performed.

In the above description, the incident angle θ of the laser beam 42 is set such that the laser absorptance of the wafer is the maximum. However, in practice, the incident angle θ may be such that it can provide, not the maximum absorptance, but a certain degree of improved absorptance. Such an incident angle is within a range between 30 degrees and 85 degrees. Preferably, the incident angle is within a range between 56 degrees and 80 degrees, because the incident angle within this range can provide a certain degree of improved absorptance for any kind of generally used films.

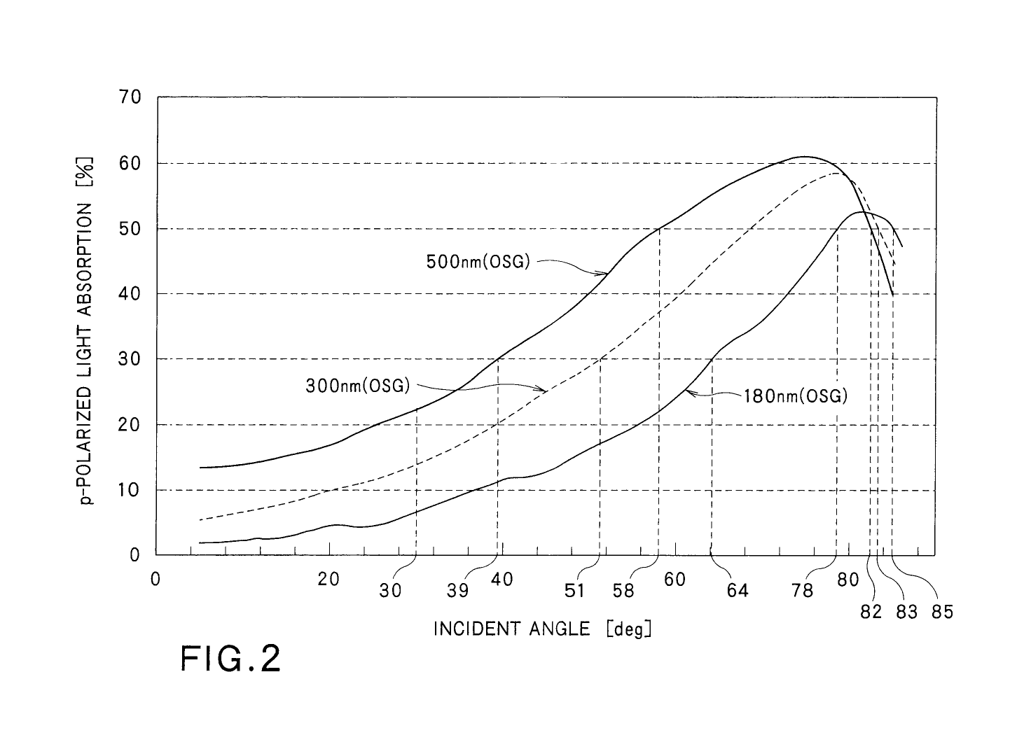

A laser absorptance for an OSG film, which was a silica film containing Si—O bonds, was measured, and a result thereof is described below. FIG. 2 is a graph showing a relationship between an incident angle and a p-polarized light absorptance, when a metal film was provided below the film. Three OSG films were used, i.e., an OSG film having a thickness of 180 nm, an OSG film having a thickness of 300 nm, and an OSG film having a thickness of 500 nm. Herein, a metal film of a Cu film having a reflection function was formed on a wafer W, and an OSG film was further formed on the metal film. A wavelength of a laser beam of p-polarized light was set to be 9.4 μm.

As apparent from the graph shown in FIG. 2, if the incident angle is small, the absorptance is significantly small. As the incident angle increases, the absorptance gradually increases. Although depending on the film thickness, at the incident angle of about 72 degrees to 80 degrees, which is near the Brewster angle, the absorptance peak appears. After that, the absorptance decreased sharply. For example, the absorptance peak appears at the angle of about 74 degrees in the 500-nm thick OSG film, at the angle of about 78 degrees in the 300-nm thick OSG film, and at the angle of about 80 degrees in the 180-nm thick OSG film. Thus, from the comprehensive standpoint, the incident angle is preferably within a range between 30 degrees and 85 degrees.

If the incident angle is smaller than 30 degrees, the absorptance undesirably decreases significantly. If the incident angle is larger than 85 degrees, the absorptance undesirably decreases sharply to zero. In particular, in order that the absorptance is 30% or more, the incident angle should be 39 degrees or more if the film thickness is 500 nm, 51 degrees or more if the film thickness is 300 nm, and 64 degrees or more if the film thickness is 180 nm. In all the cases, the upper limit is about 85 degrees.

In particular, in order that the absorptance is 50% or more, it can be understood that the incident angle is preferably within a range between 56 degrees and 82 degrees if the film thickness is 500 nm, that the incident angle is preferably within a range between 67 degrees and 83 degrees if the film thickness is 300 nm, and that the incident angle is preferably within a range between 78 degrees and 85 degrees if the film thickness is 180 nm. From the above result, it can be understood that, if the film thickness is within a range between 180 nm and 500 nm, the annealing process can be performed with a certain degree of improved absorptance, by setting the incident angle of the laser beam within a range between 60 degrees and 80 degrees.

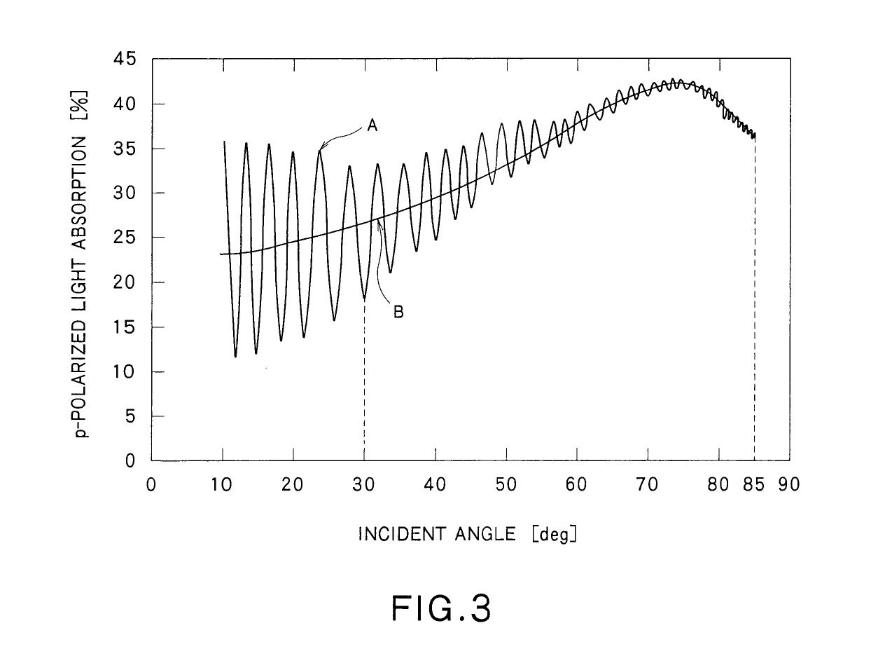

FIG. 3 is a graph showing a relationship between an incident angle and a p-polarized light absorptance, if a metal film was not provided below the OSG film. The thickness of the OSG film was 400 nm. Herein, the OSG film was directly formed on a surface of a wafer W. The wavelength of the laser beam of p-polarized light was 9.4 μm. In FIG. 3, curve A shows measured value, and curve B shows average value (smoothed value).

As shown by the curve A in FIG. 3, the measured value oscillates on about a 2-degree cycle. As shown by the curve B, the average absorptance is 23% when the incident angle is about 10 degrees. The average absorptance gradually increases as the incident angle increases. Then, the average absorptance reaches a peak of about 42% at the incident angle of about 70 degrees. Thereafter the average absorptance decreases sharply. The reason for which the measured value of the absorptance oscillates is that reflected light of the laser beam on the front surface of the wafer and reflected light of the transmission light on the rear surface of the wafer interfere with each other. Also in this case, it is understood that the incident angle is preferably within a range between 30 degrees and 85 degrees.

With the foregoing layered structure, as described above, the measured value of the absorptance oscillates on about a 2-degree cycle. Since the optical path length is lengthened by using the multipath unit 52 as described above, the whole surface of the wafer can be scanned with the swinging angles of 0.3 degrees, which is far smaller than the oscillation cycle of 2 degrees. Thus, the laser beam can enter the wafer surface, not at an incident angle corresponding to the valley portion of the oscillation curve A, but at an incident angle corresponding to the peak portion, whereby the whole wafer surface can be scanned while maintaining the improved absorptance.

According to the present invention, the laser absorption efficiency can be significantly improved by applying a laser beam onto a surface of a target object from obliquely above at an incident angle determined in view of the laser absorptance of the film. In addition, regardless of variation in thickness of the target object, the annealing process can be stabilized, to thereby improve reproducibility of the annealing process for every target object.

### Second Embodiment

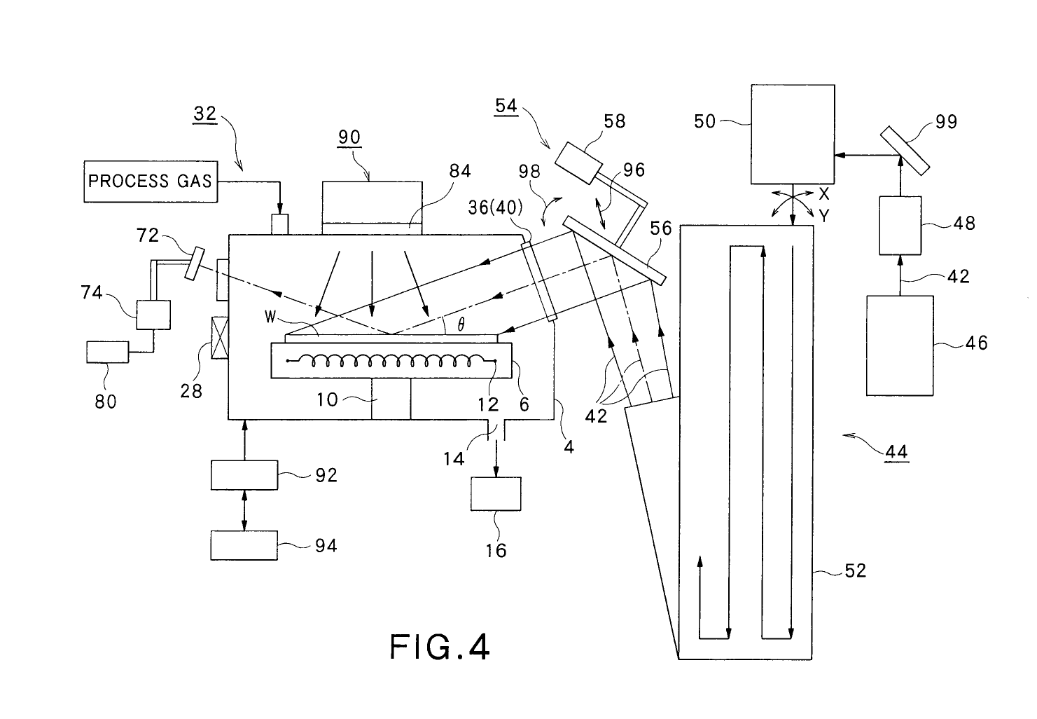

Next, a second embodiment of the annealing apparatus is described below. FIG. 4 is a schematic configuration diagram showing the second embodiment of the annealing apparatus of the present invention. FIG. 4 shows in detail a main part of the annealing apparatus in the second embodiment (part different from the first embodiment), while the other parts are omitted or simplified. In FIG. 4, the same constituent elements as those shown in FIG. 1 are designated by the same reference numbers, and duplicated description thereof is omitted.

In the first embodiment shown in FIG. 1, the multipath unit 52 is arranged above the processing vessel 4. On the other hand, as shown in FIG. 4, in the annealing apparatus 2 in the second embodiment, the multipath unit 52 is arranged to stand on a lateral side of the processing vessel 4. Also in this embodiment, the reflection mirror 56 of the incident angle adjusting mirror unit 54 can be moved in an optical axis direction as shown by an arrow 98, and an inclination angle thereof can be adjusted as shown by an arrow 98, whereby the incident angle θ of the laser beam 42 onto a wafer W can be varied. In this embodiment, a mirror 99 that varies a direction of the laser beam 42 is disposed between the beam shaper 48 and the scanner 50. The second embodiment can also exert an effect similar to that of the first embodiment.

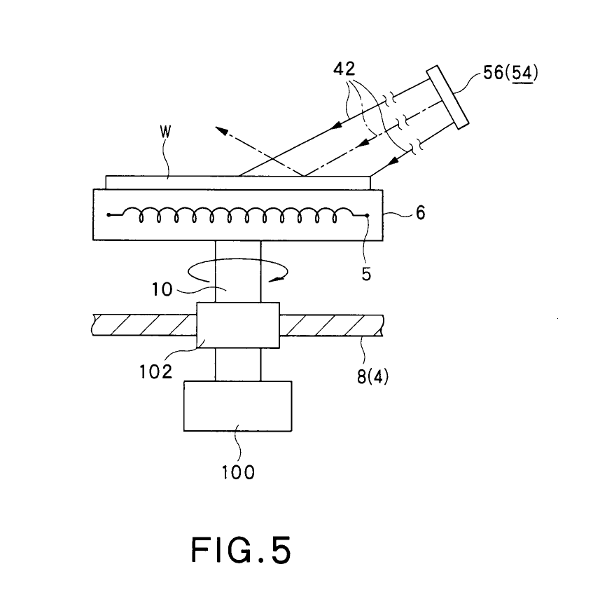

In the first and the second embodiments, the stage 6 is fixed. However, not limited thereto, the stage 6 may be rotatable. The main part of this modified embodiment is shown in FIG. 5. In FIG. 5, the same constituent elements as those shown in FIGS. 1 and 4 are shown by the same reference numbers.

As shown in FIG. 5, the column 10 supporting the stage 6 passes through the bottom part 8 of the processing vessel 4. The column 10 is connected to a rotary actuator 100, so that the column 10 can be rotated. The part of the bottom part 8 through which the column 10 passes is equipped with, e.g., a magnetic fluid seal member 102 to allow rotation of the column 10 while maintaining airtightness in the processing vessel 4.

With this structure, since the stage 6 for placing thereon a wafer W can be rotated, it is not necessary to swing the laser beam 42 such that the whole surface of the wafer W is scanned by the laser beam 42. By scanning only a fan-shaped area (sector) of the wafer W, the whole surface of the wafer is irradiated with the laser beam 42, owing to the rotation of the wafer W. Thus, the size of the reflection mirror 56 of the incident angle adjusting mirror unit 54 can be reduced to less than one half or less, as compared with that of the first and second embodiments.

In addition, as compared with the first and second embodiments, the swinging angles of the laser beam 42 for scanning can be reduced to about one half. To be specific, when performing the scanning of the laser beam 42, the rotating wafer W is scanned by the laser beam 42 in a fan-like shape.

Alternatively, as schematically shown by the chain dotted line in FIG. 1, the stage 6 may be provided with a driving unit 120 configured to translate the stage 6. The linear driving unit 120 may be configured to move the stage 6 one or both of X-direction and Y-direction. Also with this structure, the size of the reflection mirror 56 of the incident angle adjusting mirror unit 54 can be reduced.

In the above embodiments, after the semiconductor wafer W has been annealed, the film modification process is performed by irradiating the film with ultraviolet light. However, not limited thereto, although depending on the kind of the film and the process method, the annealing process and the ultraviolet modification process may be performed simultaneously, by irradiating the wafer surface with the ultraviolet light with the annealing process being performed.

In the above embodiments, O₂ gas and N₂ gas is used as the process gas. However, not limited thereto, although depending on the kind of the film kind and the process method, one or more gasses selected from the group consisting of O₂, N₂, a rare gas such as Ar and He, and H₂O.

In the above embodiment, a carbon dioxide gas laser oscillator is used as the laser oscillator 96. However, not limited thereto, another laser oscillator, such as a YAG laser oscillator, an excimer laser oscillator, a titanium-sapphire laser oscillator and a semiconductor laser oscillator, may be used depending on a film kind and a process method.

In the above embodiment, the target object is a semiconductor wafer. The semiconductor wafer includes a silicon substrate, and a substrate comprising a compound semiconductor such as GaAs, SiC and GaN. In addition, the target object is not limited to these substrates, but may be a glass substrate used in a liquid crystal display unit, and a ceramic substrate.

1. An annealing method that irradiates a target object, having a film formed on its surface, with a laser beam to perform an annealing process to the target object,
wherein the surface of the target object is irradiated with the laser beam obliquely at an incident angle that is determined to achieve an improved laser absorptance of the film.

2. The annealing method according to claim 1, wherein the incident angle is within a range between 30 degrees and 85 degrees.

3. The annealing method according to claim 1, wherein the laser beam is a laser beam of substantially p-polarized light.

4. The annealing method according to claim 1, wherein a wavelength of the laser beam is within a range between 8 μm and 10 μm.

5. The annealing method according to claim 1, wherein the film is a silica series film containing Si—O bonds.

6. The annealing method according to claim 1, wherein the annealing process is performed in a process gas atmosphere.

7. The annealing method according to claim 1, wherein an incident angle that provides maximum laser absorptance is calculated before the annealing process is performed, and the annealing process is performed using the calculated incident angle.

8. The annealing method according to claim 8, wherein the target object is rotated during the annealing process.

9. The annealing method according to claim 8, wherein the target object is translated during the annealing process.

10. An annealing apparatus that irradiates a target object, having a film formed on its surface, with a laser beam to perform an annealing process to the target object, said annealing apparatus comprising:
a processing vessel configured to accommodate the target object;
a laser beam irradiation window provided on the processing vessel;
a stage disposed in the processing vessel to hold the target object;
a laser beam irradiation unit configured to deliver a laser beam onto the surface of the target object through the laser beam irradiation window such that the surface of the target object is irradiated with the laser beam obliquely at an incident angle that is determined to achieve an improved laser absorptance of the film;
a gas supply unit configured to supply a process gas into the processing vessel; and
an exhaust unit configured to discharge an atmosphere in the processing vessel.

11. The annealing apparatus according to claim 10, wherein the incident angle is within a range between 30 degrees and 85 degrees.

12. The annealing apparatus according to claim 10, wherein the laser beam irradiation unit includes a scanner causing the laser beam to scan the surface of the target object.

13. The annealing apparatus according to claim 12, wherein the laser beam irradiation unit includes a multipath unit disposed on a downstream side of the scanner to extend a light path length of the laser beam.

14. The annealing apparatus according to claim 10, further comprising a rotary driving unit configured to rotate the stage.

15. The annealing apparatus according to claim 10, further comprising a driving unit configured to translate the stage.

16. The annealing apparatus according to claim 10, wherein the laser-beam irradiation unit is configured to irradiate a laser beam of substantially p-polarized light.

17. The annealing apparatus according to claim 10, wherein the laser-beam irradiation unit is configured to irradiate a laser beam having a wavelength within a range between 8 μm and 10 μm.

18. The annealing apparatus according to claim 10, wherein the laser-beam irradiation unit includes an incident angle adjusting mirror unit configured to adjust the incident angle of the laser beam incident on the surface of the target object.

19. The annealing apparatus according to claim 18, further comprising:
a reflected light detector configured to detect reflected light of the laser beam reflected from the surface of the target object; and
a mirror controller configured to adjust the incident angle adjusting mirror unit, based on a detected value of the reflected light detector.

20. The annealing apparatus according to claim 10, wherein the processing vessel is provided with an ultraviolet irradiation unit configured to deliver ultraviolet light onto the target object.

21. The annealing apparatus according to claim 10, wherein the film is a silica series film containing Si—O bonds.
